(19) United States
(12) Patent Application Publication
(10) Pub. No.: US 2020/0239360 A1
(43) Pub. Date: Jul. 30, 2020

(54) TRANSPARENT SUBSTRATE LAMINATED BODY AND METHOD FOR PRODUCING SAME

(71) Applicant: AGC Inc., Chiyoda-ku (JP)

(72) Inventors: Akihisa Minowa, Tokyo (JP); Takahiro Mashimo, Tokyo (JP); Shunji Wachi, Tokyo (JP); Hitoshi Saiki, Tokyo (JP)

(73) Assignee: AGC Inc., Chiyoda-ku (JP)

(21) Appl. No.: 16/849,011

(22) Filed: Apr. 15, 2020

Related U.S. Application Data
(63) Continuation of application No. PCT/JP2018/038903, filed on Oct. 18, 2018.

(30) Foreign Application Priority Data
Oct. 19, 2017 (JP) 2017-202884
Jun. 6, 2018 (JP) 2018-108709

(51) Int. Cl. C03C 17/42; C03C 21/00; C23C 14/00; C23C 14/06; C23C 14/10; C23C 14/12; C23C 14/34; C23C 14/24; C23C 14/58; G02B 1/18; G02B 1/11

(52) U.S. Cl. CPC C03C 17/42; C03C 21/00; C23C 14/0036; C23C 14/0652; C23C 14/10; C23C 14/12; C03C 2218/155; C23C 14/24; C23C 14/5833; G02B 1/18; G02B 1/11; C03C 2217/734; C03C 2218/151; C23C 14/34

(57) ABSTRACT

The present invention relate to a transparent substrate laminate (10) having a transparent substrate (12), an antireflection layer (14) and an antifouling layer (16) in this order, the antireflection layer (14) contains a low-refractive index layer (142) and a high-refractive index layer (144) laminating alternately, the antifouling layer (16) contains a fluorine-containing organic compound, and when washing with ethanol and washing with a fluorine solvent under specific conditions are carried out on the antifouling layer (16) in this order, the antifouling layer (16) satisfies a ratio (i)/(ii) being more than 1 in which (i) represents a fluorine amount after the washing with ethanol and (ii) represents a fluorine amount after the washing with the fluorine solvent, and in which the fluorine amount (F amount) is measured by using an X-ray fluorescence instrument (XRF).

### TECHNICAL FIELD

The present invention relates to a transparent substrate laminate and a method for manufacturing the same.

### BACKGROUND ART

In image display devices (e.g., liquid crystal displays, organic EL displays, plasma displays, etc.) provided in a variety of implements (e.g., televisions, personal computers, smartphones, mobile phones, etc.), when external light such as indoor lighting (e.g., a fluorescent lamp, etc.) or sunlight is reflected on a display surface, visibility degrades due to a reflected image. Therefore, in order to suppress the reflection of external light, techniques for providing a cover member including an antireflection layer to the display surface of an image display device have been known.

The antireflection layer has a function of suppressing the reflection of incident light, and the suppression of the reflection of incident light improves the resolution or contrast of images, the transmittance of light, and the like. As the antireflection layer, a single layer configuration of a low-refractive index material or a multiple layer configuration obtained by combining a layer formed of a low-refractive index material and a layer formed of a high-refractive index material have been known.

In order to impart an antifouling property, a surface-sliding property, and the like, there is a case where an antifouling layer is formed on the surface of the antireflection layer (Patent Literature 1). Examples of a composition for forming the antifouling layer include a silicone compound, a fluorine compound, or compositions containing both, and the antifouling layer is formed by a method such as the deposition, spraying, or dipping of the composition to the surface of the antireflection layer.

### CITATION LIST

### Patent Literature

[Patent Literature 1] JP-A-2000-144097

### SUMMARY OF INVENTION

### Technical Problem

A conventional cover member having an antireflection layer and an antifouling layer has a problem of poor abrasion resistance of the antifouling layer. Therefore, it is difficult to maintain a desired antifouling property or surface-sliding property for a long period of time. When, for example, the thickness is increased in order to enhance the abrasion resistance of the antifouling layer, the abrasion resistance of the antifouling layer can be improved, but the antireflection performance of the antireflection layer is degraded. As described above, the antireflection performance of the cover member and the abrasion resistance of the antifouling layer have a trade-off relationship, and, in the related art, it has been regarded as a difficult matter to enhance both at the same time.

Therefore, an object of the present invention is to provide: a transparent substrate laminate having a transparent substrate, an antireflection layer, and an antifouling layer in this order and being excellent in terms of the antireflection performance of the antireflection layer and the abrasion resistance of the antifouling layer; and a manufacturing method thereof.

### Solution to Problem

As a result of intensive studies, the present inventors found that a transparent substrate laminate capable of solving the above-described problem can be realized by setting the amount of fluorine contained in an antifouling layer in a specific range, and they completed the present invention.

That is, the transparent substrate laminate of the present invention has a transparent substrate, an antireflection layer and an antifouling layer in this order, the antireflection layer contains a low-refractive index layer and a high-refractive index layer laminating alternately, the antifouling layer contains a fluorine-containing organic compound, and when washing with ethanol and washing with a fluorine solvent under the following conditions are carried out on the antifouling layer in this order, the antifouling layer satisfies a ratio (i)/(ii) being more than 1 in which (i) represents a fluorine amount after the washing with ethanol and (ii) represents a fluorine amount after the washing with the fluorine solvent, and in which the fluorine amount (F amount) is measured by using an X-ray fluorescence instrument (XRF):

conditions of washing with ethanol: a non-woven fabric is impregnated with 10 mL of ethanol and moved in a uniform direction 20 times at a load of 100 g, thereby scraping a part of the antifouling layer; and

conditions of washing with a fluorine solvent: a non-woven fabric is impregnated with 10 mL of a fluorine solvent and moved in a uniform direction 20 times at a load of 100 g, thereby scraping a part of the antifouling layer.

In addition, an aspect of the method for manufacturing a transparent substrate laminate of the present invention is a method for manufacturing a transparent substrate laminate, including steps of forming an antireflection layer on a glass substrate and forming an antifouling layer on the antireflection layer, in which the antifouling layer is formed by vacuum-depositing a pelletized raw material containing a fluorine-containing organic compound at an output at which a current density on a pellet surface reaches 825.7 kA/m² or higher.

### Advantageous Effects of Invention

The transparent substrate laminate of the present invention has a ratio of the fluorine amount (F amount) of the antifouling layer after washing with ethanol and washing with a fluorine solvent under conditions described in detail in the present specification are carried out, being within a specific range. Therefore, the antireflection performance of the antireflection layer and the abrasion resistance of the antifouling layer are excellent.

### BRIEF DESCRIPTION OF DRAWINGS

FIG. 1 is a schematic cross-sectional view for describing an embodiment of a transparent substrate laminate of the present invention.

### DESCRIPTION OF EMBODIMENTS

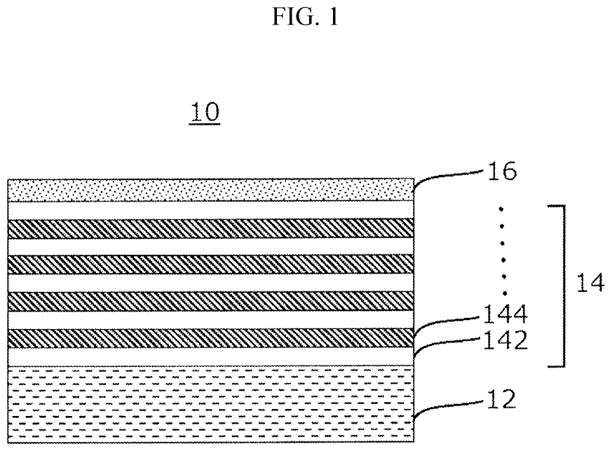

Hereinafter, an embodiment of the present invention will be further described. FIG. 1 is a schematic cross-sectional view for describing an embodiment of a transparent substrate laminate of the present invention. In FIG. 1, a transparent substrate laminate 10 has an antireflection layer 14 and an antifouling layer 16 on a transparent substrate 12 in this order. The antireflection layer 14 is formed by alternately laminating low-refractive index layers 142 and high-refractive index layers 144, and the antifouling layer 16 contains a fluorine-containing organic compound. Hereinafter, the respective layers will be described.

As the transparent substrate 12, use can be made of a transparent resin substrate or glass substrate. The resin substrate or glass substrate may have a film shape. From the viewpoint of enhancing surface hardness, heat resistance or texture, a glass substrate is preferably used as the transparent substrate 12. Examples of glass used for the glass substrate include soda-lime glass, borosilicate glass, aluminosilicate glass, alkali-free glass, sapphire glass, and the like.

From the viewpoint of protecting image display devices, the transparent substrate 12 preferably has a high mechanical strength and favorable durability against cracks. In the case where the transparent substrate 12 is a glass substrate, as a method for increasing the mechanical strength, a strengthening treatment of the glass substrate can be exemplified.

Examples of the strengthening treatment include a physical strengthening in which a glass substrate is exposed to a high temperature and then cooled by wind, and a chemical strengthening in which a glass substrate is immersed in a molten salt containing an alkali metal and an alkali metal (ion) having a small atomic diameter present on the surface of the glass substrate is replaced by the alkali metal (ion) having a larger atomic diameter present in the molten salt.

In the case where the glass substrate has a small sheet thickness as, for example, approximately 5 mm or less, the strengthening treatment is preferably a chemical strengthening.

The glass substrate treated by a chemical strengthening (hereinafter, also referred to as a chemically-strengthened glass) preferably satisfies the following conditions. That is, the chemically-strengthened glass preferably has a surface compressive stress (hereinafter, referred to as CS) of 400 MPa to 1,200 MPa and more preferably 700 MPa to 900 MPa. CS of 400 MPa or more is sufficient as a practical strength.

In addition, in the case where CS is 1,200 MPa or less, the chemically-strengthened glass is capable of withstanding a tensile stress generated inside thereof in response to the surface compressive stress, and there is no concern that the chemically-strengthened glass may naturally break. In the present invention, CS of the chemically-strengthened glass is preferably 700 MPa to 850 MPa.

Furthermore, the chemically-strengthened glass preferably has a depth of compressive stress (hereinafter, referred to as DOL) of 15 μm to 50 μm and more preferably 20 μm to 40 μm. In the case where DOL is 15 μm or more, there is no concern that the chemically-strengthened glass may be easily damaged and break.

In addition, in the case where DOL is 50 μm or less, the chemically-strengthened glass is capable of withstanding a tensile stress generated inside thereof in response to the surface compressive stress, and there is no concern that the chemically-strengthened glass may naturally break. In the present invention, DOL of the chemically-strengthened glass is preferably 25 μm to 35 μm.

The shape of the transparent substrate 12 is not limited and can be arbitrarily changed depending on the design of an image display device, attachment position, and the like. The front view may be, for example, a rectangle, a trapezoid, a circle, an ellipse, and the like. In addition, the cross-sectional view may be, for example, a rectangle, a partially curved shape, and the like.

The size of the transparent substrate 12 is appropriately determined depending on the size or use of an image display device. For example, in the case of a mobile implement, the transparent substrate 12 is preferably 30 mm×50 mm to 300 mm×400 mm and 0.1 mm to 2.5 mm in thickness. In the case of an image display device in a display device, a car navigation, a console panel, an instrument panel, or the like, the transparent substrate 12 is preferably 50 mm×100 mm to 2,000 mm×1,500 mm and 0.5 mm to 4 mm in thickness.

The thickness of the transparent substrate 12 is not particularly limited and can be set to a thickness of 10 mm or less. In the case of using the glass substrate as the transparent substrate 12, the thickness of the glass substrate is preferably 0.1 mm to 6 mm from the viewpoint of mechanical strength, transparency and the like. Particularly, in the case of use in an in-vehicle display device, the thickness is preferably 0.2 mm to 2 mm from the viewpoint of mechanical strength since safety is demanded in the glass substrate.

In the case of using the chemically-strengthened glass, the thickness of the glass substrate is, generally, preferably 5 mm or less and more preferably 3 mm or less in order to carry out the chemical strengthening treatment.

The antireflection layer 14 is a layer formed by alternately laminating high-refractive index layers 144 and low-refractive index layers 142 and formed to suppress reflection by external light and enhance the display quality of a displayed image.

The configuration of the antireflection layer 14 is not particularly limited as long as the reflection of light can be suppressed in a predetermined range. For example, the antireflection layer can be formed by alternately laminating the high-refractive index layers 144 and the low-refractive index layers 142 as described above. Here, specifically for example, the high-refractive index layer 144 refers to a layer having a refractive index of more than 1.6 for light having a wavelength of 550 nm, and the low-refractive index layer 142 refers to a layer having a refractive index of 1.6 or less for light having a wavelength of 550 nm.

The number of layers of the high-refractive index layer 144 and the low-refractive index layer 142 each in the antireflection layer 14 may be one; however, as illustrated in FIG. 1, may also be two or more. The total number of layers of the high-refractive index layers 144 and the low-refractive index layers 142 is, for example, preferably 2 to 15, more preferably 4 to 13, and still more preferably 4 to 10.

A material constituting the high-refractive index layer 144 and the low-refractive index layer 142 is not particularly limited and can be selected in consideration of the degree of an antireflection property or productivity demanded. Examples of the material constituting the high-refractive index layer 144 include niobium oxide (Nb₂O₅), titanium oxide (TiO₂), zirconium oxide (ZrO₂), tantalum oxide (Ta₂O₅), aluminum oxide (Al₂O₃), silicon nitride (Si₃N₄), and the like. One or more materials selected from these materials can be preferably used. Examples of the material constituting the low-refractive index layer 142 include silicon oxide (particularly, silicon dioxide SiO₂), a material containing a mixed oxide of Si and Sn, a material containing a mixed oxide of Si and Zr, a material containing a mixed oxide of Si and Al, and the like. One or more materials selected from these materials can be preferably used.

The outermost layer of the antireflection layer is preferably formed of SiO₂ from the viewpoint of facilitating the formation of the antifouling layer.

The antireflection layer 14 can be formed on the surface of the transparent substrate 12 preferably by a dry method, for example, a chemical vapor deposition (CVD) method or a physical vapor deposition (PVD) method, particularly, a vacuum deposition method or a sputtering method, each of which is a kind of the physical vapor deposition method.

The thickness of the antireflection layer 14 is preferably 100 nm to 500 nm. In the case where the thickness of the antireflection layer 14 is set to 100 nm or more, the reflection of external light can be effectively suppressed, which is preferable.

The antifouling layer 16 contains a fluorine-containing organic compound. The fluorine-containing organic compound is not particularly limited as long as it has any one or more characteristics of an antifouling property, a water-repellent property, an oil-repellent property, a hydrophilic property, or a lipophilic property. The antifouling layer 16 is capable of having a function of suppressing the attachment of not only a fingerprint trace but also a variety of contaminants such as sweat or dust, facilitating wiping off the contaminants, preventing the contaminants from being conspicuous, or the like.

Examples of the fluorine-containing organic compound include a perfluoroalkyl group-containing compound, a perfluoropolyether group-containing compound, and the like, and a silane compound having a perfluoropolyether group is preferably used.

Examples of the silane compound having a perfluoropolyether group include a material containing a compound represented by Formula A and/or a partially hydrolyzed condensate thereof is exemplified.

Rf³—Rf²—Z¹ Formula A

In Formula A, Rf³ is a group: CₘF₂ₘ₊₁ (here, m is an integer of 1 to 6),

Rf² is a group: —O—(CₐF₂ₐO)ₙ— (here, a is an integer of 1 to 6, n is an integer of 1 or more, and, in the case where n is 2 or more, the respective —CₐF₂ₐO— units may be identical to or different from each other), and

Z¹ is a group: -Q²-{CH₂CH(SiR²_{q}X²_{3-q})}ᵣ—H (here, Q² is —(CH₂)ₛ— (here, s is an integer of 0 to 12) or —(CH₂)ₛ— containing one or more selected from an ester bond, an ether bond, an amide bond, a urethane bond, and a phenylene group, a part or all of the —CH₂— units may be substituted by —CF₂— unit and/or —CFCF₃— unit, R² is a hydrogen atom or a monovalent hydrocarbon group having a carbon atom number of 1 to 6, the hydrocarbon group may have a substituent, X² each are independently a hydroxyl group or a hydrolyzable group, q is an integer of 0 to 2, and r is an integer of 1 to 20).

Examples of the hydrolyzable group as X² include an alkoxy group, an acyloxy group, a ketoxime group, an alkenyloxy group, an amino group, an aminooxy group, an amide group, an isocyanate group, a halogen atom, and the like. Among these, an alkoxy group, an isocyanate group and a halogen atom (particularly, a chlorine atom) are preferred from the viewpoint of the balance between stability and easiness in hydrolysis. As the alkoxy group, an alkoxy group having a carbon number of 1 to 3 is preferred, and a methoxy group or an ethoxy group is more preferred.

As a material capable of forming the antifouling layer 16, for example, use can be made of “Afluid (registered trademark) S-550” (trade name, manufactured by AGC Inc.), “KP-801” (trade name, manufactured by Shin-Etsu Chemical Co., Ltd.), “X-71” (trade name, manufactured by Shin-Etsu Chemical Co., Ltd.), “KY-130” (trade name, manufactured by Shin-Etsu Chemical Co., Ltd.), “KY-178” (trade name, manufactured by Shin-Etsu Chemical Co., Ltd.), “KY-185” (trade name, manufactured by Shin-Etsu Chemical Co., Ltd.), “KY-195” (trade name, manufactured by Shin-Etsu Chemical Co., Ltd.), “OPTOOL (registered trademark) DSX (trade name, manufactured by Daikin Industries, Ltd.)”, and the like, which are commercially available.

Examples of a method for forming the antifouling layer 16 include a vacuum deposition method (dry method) in which the fluorine-containing organic compound or the like is evaporated in a vacuum tank and forced to deposit to the surface of the antireflection layer 14.

The layer thickness of the antifouling layer 16 is not particularly limited, but is preferably 8 nm to 30 nm, more preferably 10 nm to 20 nm, and still more preferably 12 nm to 19 nm. In the case where the layer thickness is 8 nm or more, the surface of the antireflection layer 14 is uniformly covered with the antifouling layer 16, and the abrasion resistance improves. In addition, in the case where the layer thickness is 30 nm or less, optical characteristics such as luminous reflectance and haze value in a state where the antifouling layer 16 is laminated are favorable.

In the transparent substrate laminate 10 of the present embodiment, when washing with ethanol and washing with a fluorine solvent under conditions described below are carried out on the antifouling layer 16 in this order, a fluorine amount (F amount) of the antifouling layer 16 measured by using an X-ray fluorescence instrument (XRF) satisfies the ratio of a fluorine amount (i) after the washing with ethanol to a fluorine amount (ii) after the washing with a fluorine solvent (fluorine amount (i)/fluorine amount (ii) or simply referred to as (i)/(ii)) being more than 1.

First, conditions of the washing with ethanol will be described. In the washing with ethanol, a non-woven fabric is impregnated with 10 mL of ethanol and moved in a uniform direction 20 times at a load of 100 g, thereby scraping a part of the antifouling layer. The ethanol used in the washing with ethanol is preferably a special-grade ethanol (e.g., manufactured by Kanto Chemical Co., Inc.). In addition, a conventionally-known non-woven fabric can be used; however, in order to unify test results, a non-woven fabric (manufactured by Asahi Kasei Corporation, trade name: BEMCOT M-1) is preferred, and a non-woven fabric having equivalent characteristics as this non-woven fabric can be preferably used.

Next, conditions of the washing with a fluorine solvent will be described. In the washing with a fluorine solvent, a non-woven fabric is impregnated with 10 mL of a fluorine solvent and moved in a uniform direction 20 times at a load of 100 g, thereby scraping a part of the antifouling layer.

The fluorine solvent used in the washing with a fluorine solvent is preferably a fluorine solvent (manufactured by AGC Inc., trade name: AE-3000). The fluorine solvent is not limited thereto, and a fluorine solvent having equivalent characteristics can be used. The same non-woven fabric as used in the washing with ethanol can be used.

Conditions of the XRF measurement are as described below. The intensity evaluation of the F amount was carried out by using an X-ray fluorescence instrument (e.g., manufactured by Rigaku Corporation, instrument name: ZSX100e) on a transparent substrate laminate that has been subjected to the respective washing treatments as described above. The aperture of a specimen cell used was 30 mmø.

In the present embodiment, the fluorine amount (F amount) of the antifouling layer 16 satisfies the ratio (i)/(ii) of the fluorine amount (i) after the washing with ethanol to the fluorine amount (ii) after the washing with a fluorine solvent of more than 1. The ratio is preferably 1.1 or more, more preferably 1.2 or more, and still more preferably more than 1.5. In the case where the ratio (i)/(ii) exceeds 1, the amount of the fluorine-containing organic compound present in a state of being unbound or loosely physically interlocked in the antifouling layer 16 increases. In addition, it is considered that, when the antifouling layer 16 is rubbed, this fluorine-containing organic compound present in a state of being unbound or loosely physically interlocked is preferentially removed, and the fluorine-containing organic compound of the antifouling layer 16 strongly bonding to the antireflection layer 14 is protected and left for a long period of time, whereby the abrasion resistance can be improved. On the other hand, the ratio (i)/(ii) is, generally, preferably 3 or less from the viewpoint of suppressing decrease in the transmittance of the transparent substrate laminate 10.

Examples of the method for controlling the ratio (i)/(ii) within the range defined in the present invention include (1) a method of flattening the outermost layer of the antireflection layer 14 on which the antifouling layer 16 is laminated and (2) a method of increasing the fluorine-containing organic compound to be deposited in a monomolecular state at the time of forming the antifouling layer 16 by vacuum deposition.

In the case where the outermost layer of the antireflection layer 14 on which the antifouling layer 16 is laminated is flattened as in the method (1), the outermost layer of the antireflection layer 14 preferably has a surface roughness Ra of 0.8 nm or less, more preferably 0.6 nm or less, and still more preferably 0.5 nm or less. The surface roughness Ra is generally 0.1 nm or more. The surface roughness Ra can be measured according to JIS B 0601-2001.

Examples of the method for achieving the surface roughness Ra of the outermost layer of the antireflection layer 14 include any of means (1-1) to (1-4) described below and a combination thereof.

(1-1) Increasing the degree of cleanness of the surface of the transparent substrate 12. The degree of cleanness of the surface of the transparent substrate 12 can be increased by appropriately adjusting the washing conditions.

(1-2) Decreasing the flow rate of Ar gas in the case of forming the antireflection layer 14 by vacuum deposition.

(1-3) Slowly evacuating the inside of a load lock chamber even in the case of forming the antireflection layer 14 by vacuum deposition.

(1-4) Carrying out a well-known linear ion source treatment (hereinafter, also abbreviated as the LIS treatment) or ion beam treatment on the outermost layer after the lamination of the antireflection layer 14, or on each layer.

Examples of the method for increasing the fluorine-containing organic compound to be deposited in a monomolecular state at the time of forming the antifouling layer 16 by vacuum deposition as in the method (2), include any of means described below and a combination thereof.

(2-1) Pelletizing a composition containing the fluorine-containing organic compound. Accordingly, the amount of moisture in the composition is decreased, thereby suppressing the inhibition of deposition by moisture, impurities and the like and increasing the fluorine-containing organic compound to be deposited in a monomolecular state.

(2-2) Increasing the deposition output to increase the temperature of the pellets at the time of forming the antifouling layer 16 by vacuum deposition. Accordingly, the inhibition of deposition by moisture, impurities and the like can be suppressed, and the fluorine-containing organic compound to be deposited in a monomolecular state can be increased. The output is preferably 825.7 kA/m² or higher and more preferably 1,003 kA/m² or higher in terms of the current density. In the case where the output is set within this range, after the beginning of deposition, the pellets instantly reach a high temperature and evaporated. Therefore, the probability of the pellets reacting with H₂O in a film formation device decreases, and the fluorine-containing organic compound to be deposited in a monomolecular state can be increased. Furthermore, in the case where the output is set within this range, AFP in a monomolecular state is first deposited, and condensed AFP in a bimolecular state forms a film thereafter. Therefore, the fluorine amount (F amount) of the antifouling layer 16 measured by using an X-ray fluorescence instrument (XRF) can be set within a range defined in the present invention as the ratio (i)/(ii) of the fluorine amount (i) after the washing with ethanol to the fluorine amount (ii) after the washing with a fluorine solvent.

(2-3) Carrying out a blast treatment on an adhesion-preventing plate for preventing the attachment of the fluorine-containing organic compound to the inside of the device in the case of forming the antifouling layer 16 by vacuum deposition. Accordingly, the amount of moisture in a vacuum chamber is decreased, whereby the inhibition of deposition by moisture, impurities and the like can be suppressed, and the fluorine-containing organic compound to be deposited in a monomolecular state can be increased.

The transparent substrate laminate 10 of the present embodiment preferably has a water contact angle measured by a steel wool abrasion test under the following conditions, being 80° or more, more preferably 90° or more, still more preferably 100° or more, and further more preferably 1050 or more. The water contact angle is generally less than 1200. In the case where the water contact angle of the transparent substrate laminate 10 is 80° or more, particularly 100° or more, excellent antifouling property, scratch resistance, and surface-sliding property can be maintained for a long period of time.

Conditions of steel wool abrasion test: a surface of the antifouling layer 16 is abraded 5,000 times by using #0000 steel wool attached to a 1 cm²-indenter under conditions of a load of 1 kgf, a stroke width of 40 mm, a speed of 80 rpm, 25° C., and 50% RH, by using a plane abrasion tester (triple-barrel) (manufactured by Daiei Kagaku Seiki MFG. Co., Ltd., device name: PA-300A). After that, the water contact angle of the surface of the antifouling layer 16 is measured.

The transparent substrate laminate 10 of the present embodiment preferably has a water contact angle measured by an eraser abrasion test under the following conditions, being 80° or more, more preferably 90° or more, still more preferably 100° or more, and further more preferably 105° or more. The water contact angle is generally less than 120°. In the case where the water contact angle of the transparent substrate laminate 10 is 80° or more, particularly 100° or more, excellent antifouling property, scratch resistance, and surface-sliding property can be maintained for a long period of time.

Conditions of eraser abrasion test: a surface of the antifouling layer 16 is abraded 3,000 times by using an eraser having a diameter of 6 mm (PINKPENCIL, manufactured by Woojin Inc.) under conditions of a load of 1 kgf, a stroke width of 40 mm, a speed of 80 rpm, 25° C., and 50% RH, by using a plane abrasion tester (triple-barrel) (manufactured by Daiei Kagaku Seiki MFG. Co., Ltd., device name: PA-300A). After that, the water contact angle of the surface of the antifouling layer 16 is measured.

The transparent substrate laminate 10 of the present embodiment preferably has an average reflectance at a wavelength of 400 nm to 700 nm being 5% or less after washing with ethanol described below. In the case where the average reflectance is low, reflection of external light can be reduced when the transparent substrate laminate of the present embodiment is installed on a display surface of an image display device and used as a cover member, which is preferable. For the same reason, the average reflectance is more preferably 3% or less and particularly preferably 1% or less.

The washing with ethanol is carried out in a manner such that a non-woven fabric is impregnated with 10 mL of ethanol and moved in a uniform direction 20 times at a load of 100 g, thereby scraping a part of the antifouling layer 16. The ethanol used in this washing with ethanol is preferably a special-grade ethanol (e.g., manufactured by Kanto Chemical Co., Inc.), and the non-woven fabric is preferably a non-woven fabric (manufactured by Asahi Kasei Corporation, trade name: BEMCOT M-1).

The transparent substrate laminate 10 of the present embodiment may have an additional functional layer other than the antireflection layer 14 and the antifouling layer 16. Examples of the additional functional layer include an antiglare layer, a light-shielding layer, and the like.

In the case where the transparent substrate laminate has an antiglare layer, the normal reflection component of external light can be reduced. The antiglare layer can be formed by providing concavity and convexity to the transparent substrate. Examples of a method for providing these concavity and convexity include a method of providing concavity and convexity by etching the transparent substrate and a method of providing concavity and convexity by fixing fine particles to the transparent substrate by using a matrix resin.

In the case where the transparent substrate laminate has a light-shielding layer, a mark can be formed on the transparent substrate laminate, and wires on a rear surface of the transparent substrate laminate 10 can be hidden. The light-shielding layer is preferably provided on a surface of the transparent substrate, on which the antireflection layer 14 is not provided. The light-shielding layer can be formed by applying a conventionally-known coloring ink to a predetermined position and fixing the ink to the transparent substrate.

The transparent substrate laminate 10 of the present embodiment is useful as a cover member having an antireflection function and an antifouling function on, for example, display surfaces of image display devices (e.g., liquid crystal displays, organic EL displays, plasma displays, etc.) provided in a variety of implements (e.g., televisions, personal computers, smartphones, mobile phones, etc.).

### EXAMPLES

Hereinafter, the present invention will be more described by referring to Examples and Comparative Examples, but the present invention is not limited to the following examples. Examples 1 to 3 are Invention Examples, and Example 4 is Comparative Example.

Transparent substrate laminates obtained in the respective examples described below were evaluated as described below.

(Fluorine Amount (F Amount) Measurement)

For the transparent substrate laminates, the fluorine amount (F amount) of the antifouling layer was measured by using an X-ray fluorescence instrument (XRF) when washing with ethanol and washing with a fluorine solvent described below were carried out in this order. The ratio (i)/(ii) of the fluorine amount (i) after the washing with ethanol to the fluorine amount (ii) after the washing with a fluorine solvent was computed.

Conditions of the washing with ethanol: a non-woven fabric (manufactured by Asahi Kasei Corporation, trade name: BEMCOT M-1) was impregnated with 10 mL of special-grade ethanol (manufactured by Kanto Chemical Co., Inc.) and moved in a uniform direction 20 times at a load of 100 g, thereby scraping a part of the antifouling layer. Conditions of the washing with a fluorine solvent: a non-woven fabric (manufactured by Asahi Kasei Corporation, trade name: BEMCOT M-1) was impregnated with 10 mL of a fluorine solvent (manufactured by AGC Inc., trade name: AE-3000) and moved in a uniform direction 20 times at a load of 100 g, thereby scraping a part of the antifouling layer.

(Contact Angle Measurement)

After the water contact angle (initial water contact angle) of the antifouling layer of the transparent substrate laminate was measured, a steel wool abrasion test and an eraser abrasion test described below were carried out on the antifouling layer.

(Steel wool abrasion test) A surface of the antifouling layer 16 was abraded 5,000 times by using #0000 steel wool attached to a 1 cm²-indenter under conditions of a load of 1 kgf, a stroke width of 40 mm, a speed of 80 μm, 25° C., and 50% RH, by using a plane abrasion tester (triple-barrel) (manufactured by Daiei Kagaku Seiki MFG. Co., Ltd., device name: PA-300A). After that, the water contact angle of the surface of the antifouling layer was measured.

(Eraser Abrasion Test)

A surface of the antifouling layer 16 was abraded 3,000 times by using an eraser having a diameter of 6 mm (PINKPENCIL, manufactured by Woojin Inc.) under conditions of a load of 1 kgf, a stroke width of 40 mm, a speed of 80 rpm, 25° C., and 50% RH, by using a plane abrasion tester (triple-barrel) (manufactured by Daiei Kagaku Seiki MFG. Co., Ltd., device name: PA-300A). After that, the water contact angle of the surface of the antifouling layer was measured.

(Average Reflectance)

The average reflectance at a wavelength of 400 nm to 700 nm of the transparent substrate laminate after the washing with ethanol was obtained by using a spectrophotometer (manufactured by Hitachi High-Technologies Corporation, device name: U-4100).

### Example 1

As a transparent substrate, a glass substrate [manufactured by AGC Inc., trade name: DRAGONTRAIL (registered trademark)] was prepared. An antireflection layer was formed on a main surface of the glass substrate by repeating the alternate formation of a silicon oxide film (SiO₂ film) as a low-refractive index layer and a silicon nitride film (Si₃N₄ film) as a high-refractive index layer by a radical assisted sputtering (RAS) method by using a load lock type sputtering device (manufactured by Shincron Co., Ltd., device name: RAS-1100BII). The thicknesses of the respective layers of the antireflection layer are as shown in Table 1.

For the formation of the high and low-refractive index layers, a silicon target (manufactured by Maruyasu & Co., Ltd., trade name: polycrystal Si target) was used. The high-refractive index layer was formed under the following conditions. Ar gas was introduced at a flow rate of 120 sccm as a sputtering gas, and N₂ gas was introduced at a flow rate of 110 sccm as a reactive gas. The input power was set to 7.0 kW, the RF power was set to 1 kW, the substrate temperature was set to normal temperature (25° C.), and the film formation rate was set to 0.2 nm/min. The low-refractive index layer was formed under the following conditions. Ar gas was introduced at a flow rate of 120 sccm as a sputtering gas, and O₂ gas was introduced at a flow rate of 110 sccm as a reactive gas. The input power was set to 7.5 kW, the RF power was set to 3 kW, the substrate temperature was set to normal temperature (25° C.), and the film formation rate was set to 0.3 nm/min. Subsequently, an LIS treatment was carried out on the outermost layer of the antireflection layer. The LIS treatment was carried out under the following conditions. The pressure in a chamber was reduced to reach 2×10⁻⁵ Pa by vacuuming, thereafter, 30 sccm of argon gas was introduced to the chamber from a linear ion source, and the pressure in the chamber was adjusted to 0.4 Pa. Next, a voltage of 1,200 V was applied to an electrode unit of an LIS in the chamber, and an ion beam was generated under conditions of a current value of 0.2 A and a power of 240 W. The ion beam was radiated to the surface of the substrate while a substrate holder in which the substrate was installed was made to rotate at 60 rpm, and the treatment was carried out for 1,800 seconds.

Subsequently, “KY-195 (20.6% by weight)” (trade name, manufactured by Shin-Etsu Chemical Co., Ltd.) was used by being pelletized, and vacuum-deposited, thereby forming an antifouling layer having a thickness of approximately 20 nm. The output of the vacuum deposition was set to 1,003 kA/m² which was 85% in the case of taking the current density of the pellet surface of 1,180 kA/m² as 100%.

In this manner, a transparent substrate laminate was obtained.

The results are all shown in Table 1.

### Example 2

A transparent substrate laminate was manufactured in the same manner as in Example 1 except that the LIS treatment was not carried out on the outermost layer of the antireflection layer in Example 1.

The results are all shown in Table 1.

### Examples 3 and 4

Transparent substrate laminates were manufactured in the same manner as in Example 1 except that the LIS treatment was not carried out on the outermost layer of the antireflection layer and the output was changed to 72% (849.3 kA/m²) in Example 1.

The results are all shown in Table 1.

### Examples 5 and 6

Transparent substrate laminates were manufactured in the same manner as in Example 1 except that the output was changed to 72% (849.3 kA/m²) in Example 1.

The results are all shown in Table 1.

### Comparative Example 1

A transparent substrate laminate was manufactured in the same manner as in Example 1 except that the LIS treatment on the antireflection layer was not carried out and “KY-195 (20.6% by weight)” (trade name, manufactured by Shin-Etsu Chemical Co., Ltd.) was not pelletized.

The results are all shown in Table 1.

### Comparative Example 2

A transparent substrate laminate was manufactured in the same manner as in Example 1 except that the LIS treatment on the antireflection layer was not carried out, “KY-195 (20.6% by weight)” (trade name, manufactured by Shin-Etsu Chemical Co., Ltd.) was not pelletized, and the output was changed to 72% (849.3 kA/m²) in Example 1.

The results are all shown in Table 1.

TABLE 1

| | | | | | | | Comp. | Comp. |
|---|---|---|---|---|---|---|---|---|
| | Ex. 1 | Ex. 2 | Ex. 3 | Ex. 4 | Ex. 5 | Ex. 6 | Ex. 1 | Ex. 2 |
| Structure of | SiO₂ (thick- | Same as | Same as | Same as | Same as | Same as | Same as | Same as |
| antireflection | ness: 85.6 nm) | left | left | left | left | left | left | left |
| layer [config- | Si₃N₄ (thick- | | | | | | | |
| uration from | ness: 76.6 nm) | | | | | | | |
| antireflection | SiO₂ (thick- | | | | | | | |
| layer side | ness: 18.5 nm) | | | | | | | |
| (upper row side) | Si₃N₄ (thick- | | | | | | | |
| toward trans- | ness: 35.6 nm) | | | | | | | |
| parent substrate | SiO₂ (thick- | | | | | | | |
| side (lower row | ness: 76.2 nm) | | | | | | | |
| side)] | Si₃N₄ (thick- | | | | | | | |
| | ness: 12.0 nm) | | | | | | | |
| | SiO₂ (thick- | | | | | | | |
| | ness: 86.7 nm) | | | | | | | |
| | Si₃N₄ (thick- | | | | | | | |
| | ness: 10.0 nm) | | | | | | | |
| | SiO₂ (thick- | | | | | | | |
| | ness: 24.0 nm) | | | | | | | |
| Ra of antireflection | 0.35 | 0.63 | 0.57 | 0.55 | 0.35 | 0.36 | 0.89 | 0.86 |
| layer (nm) | | | | | | | | |
| Thickness of | 20 | 18 | 19 | 19 | 19 | 19 | 18 | 18 |
| antifouling layer | | | | | | | | |
| (nm) | | | | | | | | |
| F amount after | 1.35 | 0.84 | 0.71 | 0.74 | 0.55 | 0.59 | 0.51 | 0.52 |
| washing with | | | | | | | | |
| ethanol (i) | | | | | | | | |
| F amount after | 0.52 | 0.51 | 0.51 | 0.51 | 0.5 | 0.5 | 0.51 | 0.5 |
| washing with | | | | | | | | |
| fluorin esolvent (ii) | | | | | | | | |
| Ratio (i)/(ii) | 2.6 | 1.6 | 1.4 | 1.4 | 1.1 | 1.1 | 1.0 | 1.0 |
| Initial water | 115 | 116 | 118 | 118 | 112 | 112 | 116 | 114 |
| contact angle (°) | | | | | | | | |
| Water contact angle | 110 | 98 | 89 | 79 | 72 | 82 | 42 | 28 |
| after steel wool | | | | | | | | |
| abrasion test (°) | | | | | | | | |
| Water contact angle | 112 | 96 | 95 | 98 | 84 | 94 | 66 | 53 |
| after eraser | | | | | | | | |
| abrasion test (°) | | | | | | | | |
| Average reflectance | 0.8 | 0.8 | 0.8 | 0.8 | 0.8 | 0.8 | 0.8 | 0.8 |
| (%) (400 to 700 nm) | | | | | | | | |

From the results shown in Table 1, it is found that, in the transparent substrate laminates in which the fluorine amount (F amount) of the antifouling layer satisfies the ratio (i)/(ii) of the fluorine amount (i) after the washing with ethanol to the fluorine amount (ii) after the washing with a fluorine solvent being more than 1, the antireflection performance does not deteriorate, and the abrasion resistance of the antifouling layer also improves since a decrease in the water contact angle after the abrasion tests is suppressed.

In addition, from the test conditions of Examples 1 to 6 and Comparative Examples 1 and 2 and the result shown in Table 1, it is found that, when the composition containing the fluorine-containing organic compound is pelletized and deposited at an output of 70% (825.7 kA/m² in terms of the current density) or higher, the ratio (i)/(ii) of the fluorine amount (i) after the washing with ethanol to the fluorine amount (ii) after the washing with a fluorine solvent reaches more than 1, and the abrasion resistance of the antifouling layer also improves. In addition, it is found that, when the deposition output is set to 85% (1,003 kA/m² in terms of the current density) or higher, the ratio (i)/(ii) and the abrasion resistance of the antifouling layer also improves. Particularly, it is found that, when the LIS treatment is carried out on the outermost layer of the antireflection layer under a condition of the deposition output of 85% or higher, the ratio (i)/(ii) can be significantly improved, and the abrasion resistance of the antifouling layer is significantly improved.

The present invention has been described with reference to a specific embodiment, but it is clear to a person skilled in the art that a variety of modifications or corrections can be added thereto without departing from the spirit and scope of the present invention. The present application is based on a Japanese patent application (No. 2017-202884) filed on Oct. 19, 2017 and a Japanese patent application (No. 2018-108709) filed on Jun. 6, 2018, the contents of which are incorporated herein by reference.

### REFERENCE SIGNS LIST

10 transparent substrate laminate
12 transparent substrate
14 antireflection layer
142 low-refractive index layer
144 high-refractive index layer
16 antifouling layer

1. A transparent substrate laminate comprising a transparent substrate, an antireflection layer and an antifouling layer in this order,
wherein the antireflection layer comprises a low-refractive index layer and a high-refractive index layer laminating alternately,
wherein the antifouling layer contains a fluorine-containing organic compound, and
wherein when washing with ethanol and washing with a fluorine solvent under the following conditions are carried out on the antifouling layer in this order, the antifouling layer satisfies a ratio (i)/(ii) being more than 1 in which (i) represents a fluorine amount after the washing with ethanol and (ii) represents a fluorine amount after the washing with the fluorine solvent, and in which the fluorine amount is measured by using an X-ray fluorescence instrument:
conditions of the washing with ethanol: a non-woven fabric is impregnated with 10 mL of ethanol and moved in a uniform direction 20 times at a load of 100 g, thereby scraping a part of the antifouling layer; and
conditions of the washing with the fluorine solvent: a non-woven fabric is impregnated with 10 mL of the fluorine solvent and moved in a uniform direction 20 times at a load of 100 g, thereby scraping a part of the antifouling layer.

2. The transparent substrate laminate according to claim 1, wherein the transparent substrate is a glass substrate.

3. The transparent substrate laminate according to claim 1, wherein the antireflection layer has an outermost layer formed of SiO₂.

4. The transparent substrate laminate according to claim 1, having a water contact angle measured by a steel wool abrasion test under the following conditions, being 100° or more:
conditions of the steel wool abrasion test: a surface of the antifouling layer is abraded 5,000 times by using #0000 steel wool attached to a 1 cm²-indenter under conditions of a load of 1 kgf, a stroke width of 40 mm, a speed of 80 μm, 25° C., and 50% RH, by using a plane abrasion tester, and then, the water contact angle is measured.

5. The transparent substrate laminate according to claim 1, wherein the antireflection layer comprises 2 to 15 layers in total.

6. The transparent substrate laminate according to claim 1, wherein the ratio (i)/(ii) is 1.1 or more.

7. The transparent substrate laminate according to claim 1, wherein the antifouling layer has a layer thickness of 8 nm to 30 nm.

8. The transparent substrate laminate according to claim 1, wherein the antireflection layer has a surface roughness Ra of 0.8 nm or less.

9. The transparent substrate laminate according to claim 1, having an average reflectance at a wavelength of 400 nm to 700 nm being 5% or less after washing the antifouling layer with ethanol under the following conditions:
conditions of the washing with ethanol: a non-woven fabric is impregnated with 10 mL of ethanol and moved in a uniform direction 20 times at a load of 100 g, thereby scraping a part of the antifouling layer.

10. The transparent substrate laminate according to claim 2, wherein the glass substrate is a chemically-strengthened glass substrate and has a surface compressive stress of 1,200 MPa or less.

11. A method for manufacturing a transparent substrate laminate, comprising steps of:
forming an antireflection layer on a glass substrate and
forming an antifouling layer on the antireflection layer,
wherein the antifouling layer is formed by vacuum-depositing a pelletized raw material containing a fluorine-containing organic compound at an output at which a current density on a pellet surface reaches 825.7 kA/m² or higher.

12. The method according to claim 11, wherein the current density is 1003 kA/m² or higher.

13. The method according to claim 11, wherein the antifouling layer is formed by a vacuum-deposition to have a layer thickness of 8 nm to 30 nm.

14. The method according to claim 11, wherein the antireflection layer is formed by alternately laminating a low-refractive index layer and a high-refractive index layer on the glass substrate.

15. The method according to claim 11, comprising performing a linear ion source treatment or an ion beam treatment on an outermost layer of the antireflection layer.

16. The method according to claim 11, comprising performing washing with ethanol and washing with a fluorine solvent under the following conditions on the antifouling layer in this order:
conditions of the washing with ethanol: a non-woven fabric is impregnated with 10 mL of ethanol and moved in a uniform direction 20 times at a load of 100 g, thereby scraping a part of the antifouling layer; and
conditions of the washing with the fluorine solvent: a non-woven fabric is impregnated with 10 mL of the fluorine solvent and moved in a uniform direction 20 times at a load of 100 g, thereby scraping a part of the antifouling layer.

17. The method according to claim 16, wherein the antifouling layer satisfies a ratio (i)/(ii) being more than 1 in which (i) represents a fluorine amount after the washing with ethanol and (ii) represents a fluorine amount after the washing with the fluorine solvent, and in which the fluorine amount is measured by using an X-ray fluorescence instrument.
